(19) United States
(12) Patent Application Publication
(10) Pub. No.: US 2025/0337372 A1
(43) Pub. Date: Oct. 30, 2025

(54) POWER AMPLIFIER INCLUDING TWO PART MAIN SCPA CELLS

(71) Applicant: Cypress Semiconductor Corporation, San Jose, CA (US)

(72) Inventors: David SEEBACHER, Villach (AT); Edoardo BAIESI FIETTA, Padova (IT); Davide PONTON, Villach (AT); Andrea BEVILACQUA, Padova (IT)

(73) Assignee: Cypress Semiconductor Corporation, San Jose, CA (US)

(21) Appl. No.: 18/645,112

(22) Filed: Apr. 24, 2024

(51) Int. Cl. H03F 3/00; H03F 3/24; H03K 19/20; H04B 1/40

(52) U.S. Cl. CPC H03F 3/005; H03F 3/245; H03K 19/20; H04B 1/40

(57) ABSTRACT

A power amplifier includes a main switched capacitor power amplifier (SCPA) and a peak SCPA in parallel with the main SCPA. The main SCPA includes a plurality of first cells electrically coupled in parallel. Each first cell includes a first inverter, a tri-state second inverter in parallel with the first inverter, and a first capacitor electrically coupled in series with the first inverter and the second inverter. Each first cell also includes first control logic to apply a local oscillator (LO) signal to the first inverter or set the first inverter to a static logic state in response to a first control signal, and apply the LO signal to the second inverter or set the second inverter to a high-impedance state in response to a second control signal.

### BACKGROUND

High efficiency power amplifiers may be used to achieve low power consumption and long battery run times. One particular challenge is to enable high efficiency even at output power back-off for modulated signals, such as Orthogonal Frequency Division Multiplexing (OFDM) signals used in Wi-Fi, as well as for constant envelope signals, such as for Bluetooth Low Energy (BLE). For these and other reasons, a need exists for the present invention.

### SUMMARY

Some examples of the present disclosure relate to a power amplifier. The power amplifier includes a main Switched Capacitor Power Amplifier (SCPA) and a peak SCPA in parallel with the main SCPA. The main SCPA includes a plurality of first cells electrically coupled in parallel. Each first cell includes a first inverter, a tri-state second inverter in parallel with the first inverter, and a first capacitor electrically coupled in series with the first inverter and the second inverter. Each first cell also includes first control logic to apply a Local Oscillator (LO) signal to the first inverter or set the first inverter to a static logic state in response to a first control signal, and apply the LO signal to the second inverter or set the second inverter to a high-impedance state in response to a second control signal.

Other examples of the present disclosure relate to a system. The system includes a controller, a transceiver including a power amplifier, and an antenna circuit. The transceiver is communicatively coupled to the controller. The antenna circuit is electrically coupled to the transceiver. The power amplifier includes a main SCPA and a peak SCPA in parallel with the main SCPA. The main SCPA includes a plurality of first cells electrically coupled in parallel. Each first cell includes a first inverter, a tri-state second inverter in parallel with the first inverter, and a first capacitor electrically coupled in series with the first inverter and the second inverter. Each first cell also includes first control logic to apply a LO signal to the first inverter or set the first inverter to a static logic state in response to a first control signal, and apply the LO signal to the second inverter or set the second inverter to a high-impedance state in response to a second control signal.

Yet other examples of the present disclosure relate to a method. The method includes receiving an input signal at a power amplifier. The method includes generating a main output signal component via a main SCPA of the power amplifier based on the input signal. The main SCPA includes a plurality of first cells electrically coupled in parallel. Each first cell includes a first inverter and a tri-state second inverter in parallel with the first inverter. The first inverter and the second inverter are each activated or inactivated based on the input signal. The method includes generating a peak output signal component via a peak SCPA of the power amplifier. The method includes generating an output signal in response to the main output signal component and the peak output signal component.

### BRIEF DESCRIPTION OF THE DRAWINGS

FIG. 1 is a schematic diagram illustrating an example power amplifier.

FIGS. 2A and 2B are schematic diagrams illustrating example power amplifiers including two part main SCPA cells.

FIG. 3A-8B are charts illustrating a comparison between a power amplifier including two part main SCPA cells versus a similarly configured power amplifier not including two part main SCPA cells.

FIG. 9 is a block diagram illustrating one example of a system including a power amplifier.

FIGS. 10A and 10B are flow diagrams illustrating an example method for generating an output signal via a power amplifier.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

Switched Capacitor Power Amplifiers (SCPAs) provide good linearity as well as direct digital to analog conversion without the need of a baseband Digital to Analog Converter (DAC) and mixers to generate the signal. Due to the behavior of SCPAs as voltage sources, SCPAs may be used for voltage mode Doherty implementations without the need of impedance inversion. SCPA Doherty implementations may suffer from increased capacitive losses in the final stage, as well as in the driving lineup, compared to a standalone implementation for low power since the devices are oversized to enable delivery of peak power.

Accordingly, disclosed herein is an efficient implementation of the driver lineup for a main SCPA to minimize the capacitive driving losses in the low power mode. In this way, the optimization of the power amplifier sizing for both high power and low power may be decoupled.

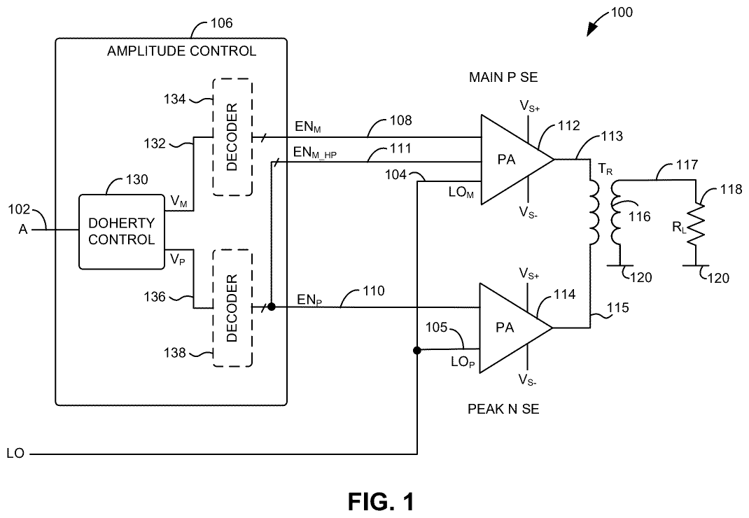

FIG. 1 is a schematic diagram illustrating one example of a power amplifier 100. Power amplifier 100 may include a voltage mode SCPA (e.g. Doherty) using single ended power amplifier stages. In some examples, power amplifier 100 is a class-D amplifier. Power amplifier 100 includes amplitude control 106, a main SCPA 112 (i.e., MAIN P SE), a peak SCPA 114 (i.e., PEAK N SE), a transformer (TR) 116 (e.g., balun), and a load resistance (RL) 118. In some examples, load resistance 118 represents an antenna circuit. An input of amplitude control 106 receives an input signal (A), representing amplitude information, on a signal path 102. In some examples, the input signal A may include a digital signal including a digital code for controlling power amplifier 100. Amplitude control 106 may include Doherty control 130, a first decoder 134, and a second decoder 138.

The input signal A is input to Doherty control 130. A first output of Doherty control 130 is electrically coupled to the input of first decoder 134 through a main voltage control signal (V_{M}) path 132. A second output of Doherty control 130 is electrically coupled to the input of second decoder 138 through a peak voltage control signal (V_{P}) path 136. The output of first decoder 134, which is a first output of amplitude control 106, is electrically coupled to a first control input of main SCPA 112 through an enable main (e.g., first) control signal (EN_{M}) path 108 to enable (e.g., activate) selected first parts of main SCPA 112. The output of second decoder 138, which is a second output of amplitude control 106, is electrically coupled to a second control input of main SCPA 112 through an enable main high power (e.g., second) control signal (EN_{M_HP}) path 111 to enable (e.g., activate) selected second parts of main SCPA 112. The output of second decoder 138, which is a third output of amplitude control 106, is electrically coupled to a control input of peak SCPA 114 through an enable peak (e.g., second) control signal (ENP) path 110 to enable (e.g., activate) selected parts of peak SCPA 114. It is noted that EN_{M_HP}, which is input to main SCPA 112 and EN_{P}, which is input to peak SCPA 114, are the same second control signal. In some examples, first decoder 134 and second decoder 138 may be excluded and Doherty control 130 may directly generate the EN_{M}, EN_{M_HP}, and EN_{P} signals.

A Local Oscillator (LO) input of the main SCPA 112 receives a LO signal through a main local oscillator signal (LOM) path 104. A LO input of the peak SCPA 114 receives the LO signal through a peak local oscillator signal (LO_{P}) path 105. It is noted that the LOM signal and the LO_{P} signal are the same LO signal. The output of main SCPA 112 is electrically coupled to a first terminal of a primary winding of transformer 116 through a signal path 113, and the output of peak SCPA 114 is electrically coupled to a second terminal of the primary winding of transformer 116 through a signal path 115. A first terminal of a secondary winding of transformer 116 is electrically coupled to one side of load resistance 118 through a signal path 117, and a second terminal of the secondary winding of transformer 116 is electrically coupled to a common or ground node 120. The other side of load resistance 118 is electrically coupled to the common or ground node 120. Both the main SCPA 112 and the peak SCPA 114 are powered by a single supply voltage (V_{S+}/V_{S-}).

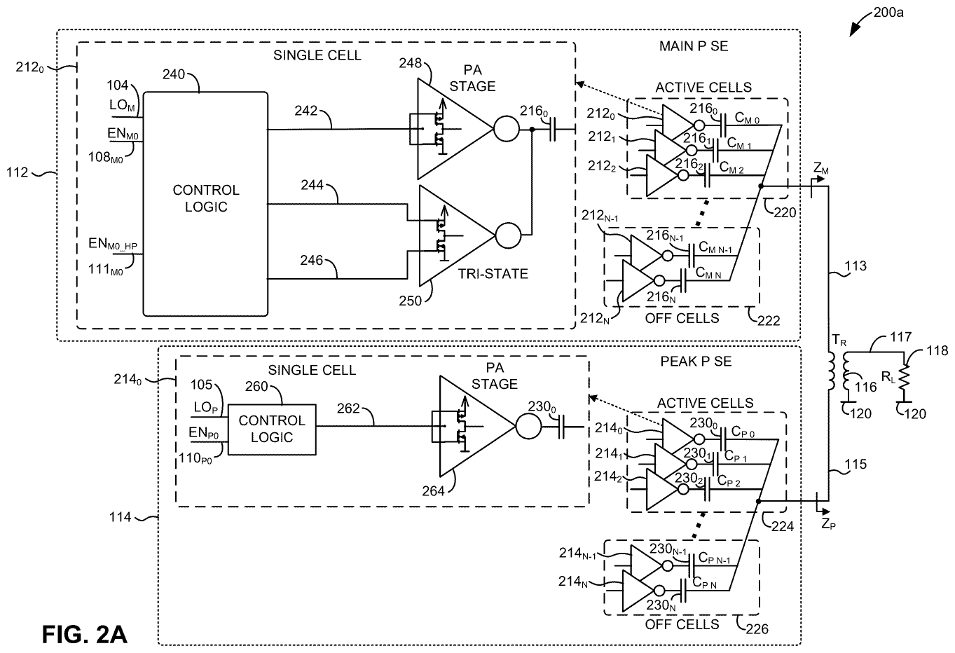

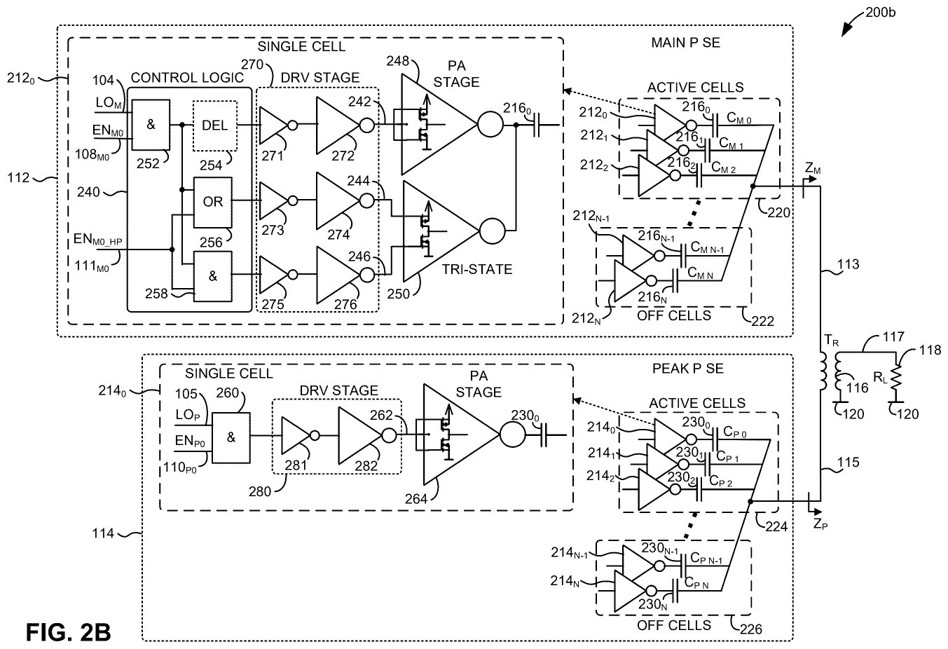

As will be further described below with reference to FIGS. 2A and 2B, main SCPA 112 and peak SCPA 114 may each include a plurality of cells electrically coupled in parallel. The output voltage/power of the power amplifier 100 is modified by selecting the number of active cells that are switching between the power supply and ground. The input signal A may include a digital code indicating which cells of the main SCPA 112 and the peak SCPA 114 are to be activated based on the desired output voltage/power of the power amplifier 100. Amplitude control 106 may decode the digital code to generate a first control signal EN_{M} to activate first parts of selected cells of the main SCPA 112. Amplitude control 106 may also decode the digital code to generate a second control signal EN_{P} and EN_{M_HP} to activate selected cells of the peak SCPA 114 and second parts of selected cells of the main SCPA 112, respectively. The combined output of each of the activated cells of the main SCPA 112 and the peak SCPA 114 is applied to transformer 116 and the load resistance 118.

FIG. 2A is a schematic diagram illustrating an example power amplifier 200a. Power amplifier 200a may include a voltage mode SCPA (e.g. Doherty) using single ended power amplifier stages. In some examples, power amplifier 200a may provide or form a part of power amplifier 100 of FIG. 1. In some examples, power amplifier 200a is a class-D amplifier. Power amplifier 200a includes a main SCPA 112 (i.e., MAIN P SE), a peak SCPA 114 (i.e., PEAK N SE), a transformer 116, and a load resistance 118.

Main SCPA 112 includes a plurality of first cells electrically coupled in parallel. Each first cell includes a first portion 212₀ to 212_{N} and a first capacitor 216₀ to 216_{N} electrically coupled in series with the first portion 2120 to 212N, respectively, where “N” is any suitable number of first cells. Each first capacitor 216₀ to 216_{N} has a capacitance C_{M 0} to C_{M N}, respectively. In some examples, each capacitance C_{M 0} to C_{M N} is equal. In other examples, the capacitances C_{M 0} to CMN may be binary weighted. A detailed view of first portion 212₀ is illustrated on the left side of main SCPA 112. The other first portions 212₁ to 212_{N} are similar to first portion 212₀.

Each first cell includes first control logic 240, a first inverter 248, a tri-state second inverter 250 in parallel with the first inverter 248, and a first capacitor 216 (e.g., 2160 in the illustrated example) coupled in series with the first inverter 248 and the tri-state second inverter 250. Each first inverter 248 may include a high side switch and a low side switch connected to the high side switch at a drain node. Each second tri-state inverter 250 may include a high side switch and a low side switch connected to the high side switch at a drain node. A first input of control logic 240 receives a main local oscillator signal (LOM) on signal path 104. A second input of control logic 240 receives a first control signal EN_{M} (e.g., EN_{M0} for the first main SCPA cell 212₀, 216₀ in the illustrated example) on a signal path 108 (e.g., 108_{M0}, which is one signal line of signal path 108 of FIG. 1 in the illustrated example). A third input of control logic 240 receives a second control signal EN_{M_HP} (e.g., EN_{M0_HP} for the first main SCPA cell 212₀, 216₀ in the illustrated example) on a signal path 111 (e.g., 111_{M0}, which is one signal line of signal path 111 of FIG. 1 in the illustrated example).

A first output of control logic 240 is electrically coupled to the input (e.g., both the high side switch and the low side switch) of first inverter 248 through a signal path 242. A second output of control logic 240 is electrically coupled to a first input (e.g., high side switch) of tri-state second inverter 250 through a signal path 244. A third output of control logic 240 is electrically coupled to a second input (e.g., low side switch) of tri-state second inverter 250 through a signal path 246. The output of first inverter 248 and the output of tri-state second inverter 250 are electrically coupled to a first terminal of capacitor 2160. A second terminal of capacitor 2160 is electrically coupled to the first terminal of the primary winding of transformer 116 through signal path 113.

First control logic 240 is configured to apply the LOM signal to the first inverter 248 or set the first inverter to a static (e.g., unchanging) logic state (e.g., a static logic high state or a static logic low state) in response to the first control signal EN_{M0}. For example, in response to a logic high EN_{M0} signal, control logic 240 may apply the LOM signal to the input of first inverter 248, such that the first inverter 248 is active (e.g., enabled). In response to a logic low EN_{M0} signal, control logic 240 may apply a static logic low signal to the input of first inverter 248, such that the first inverter 248 is inactive (e.g., off, disabled).

First control logic 240 is also configured to apply the LOM signal to the second inverter 250 or set the second inverter 250 to a high-impedance state in response to the second control signal EN_{M0_HP}. For example, in response to a logic high EN_{M0_HP} signal, control logic 240 may apply the LOM signal to both inputs (e.g., the high side switch and the low side switch) of second inverter 250, such that the second inverter 250 is active (e.g., enabled). In response to a logic low EN_{M0_HP} signal, control logic 240 may apply a logic low signal to both inputs (e.g., the high side switch and the low side switch) of second inverter 250, such that the output of second inverter 250 exhibits a high-impedance state (e.g., is floating or tri-stated).

Peak SCPA 114 includes a plurality of second cells electrically coupled in parallel. Each second cell includes a second portion 214₀ to 214_{N} and a second capacitor 230₀ to 230_{N} electrically coupled in series with the second portion 214₀ to 214_{N}, respectively. Each second capacitor 230₀ to 230_{N} has a capacitance C_{P 0} to C_{P N}, respectively. In some examples, each capacitance C_{P 0} to C_{P N} is equal. In other examples, the capacitances C_{P 0} to C_{P N} may be binary weighted. A detailed view of second portion 214₀ is illustrated on the left side of peak SCPA 114. The other second portions 214₁ to 214_{N} are similar to second portion 214₀.

Each second cell includes second control logic 260, a third inverter 264, and a second capacitor 230 (e.g., 230₀ in the illustrated example) coupled in series with the third inverter 264. Each third inverter 264 may include a high side switch and a low side switch connected to the high side switch at a drain node. A first input of control logic 260 receives a peak local oscillator signal (LO_{P}) on signal path 105. A second input of control logic 260 receives the second control signal EN_{P} (e.g., EN_{P0} for the first peak SCPA cell 214₀, 230₀ in the illustrated example) on a signal path 110 (e.g., 110_{P0}, which is one signal line of signal path 110 of FIG. 1 in the illustrated example). The output of control logic 260 is electrically coupled to the input (e.g., both the high side switch and the low side switch) of third inverter 264 through a signal path 262. The output of third inverter 264 is electrically coupled to a first terminal of capacitor 230₀. A second terminal of capacitor 2300 is electrically coupled to the second terminal of the primary winding of transformer 116 through signal path 115.

Second control logic 260 is configured to apply the LO_{P} signal to the third inverter 264 or set the third inverter to a static (e.g., unchanging) logic state (e.g., a static logic high state or a static logic low state) in response to the second control signal EN_{P0}. For example, in response to a logic high EN_{P0} signal, control logic 260 may apply the LO_{P} signal to the input of third inverter 264, such that the peak SCPA cell is active (e.g., enabled). In response to a logic low EN_{P0} signal, control logic 246 may apply a static logic low signal to the input of third inverter 264, such that the peak SCPA cell is inactive (e.g., off, disabled).

The first part (e.g., inverter 248) of each first cell of main SCPA 112 may be enabled (e.g., activated) or disabled (e.g., shut off) via a control signal (e.g., the control signal V_{M} generated from input signal A via amplitude control 106 of FIG. 1), such that a selected first number of first parts of first cells 220 (e.g., including inverters 248 of portions 212₀ to 212₂ in the example of FIG. 2A) are active and the remaining cells 222 (e.g., including portions 212_{N-1} to 212_{N} in the example of FIG. 2A) are off. Each second cell of peak SCPA 114 may be enabled (e.g., activated) or disabled (e.g., shut off) via a control signal (e.g., the control signal V_{P} generated from input signal A via amplitude control 106 of FIG. 1), such that a selected second number of second cells 224 (e.g., including portions 214₀ to 214₂ in the example of FIG. 2A) are active and the remaining cells 226 (e.g., including portions 214_{N-1} to 214_{N} in the example of FIG. 2A) are off. With selected second cells of peak SCPA 114 active, the second part (e.g., inverter 250) of each corresponding first cell of main SCPA 112 may also be enabled (e.g., activated) via a control signal (e.g., the control signal V_{P} generated from input signal A via amplitude control 106 of FIG. 1), such that a corresponding second number of second parts of the first cells are active and the remaining second parts of the first cells are set to the high impedance state.

FIG. 2B is a schematic diagram illustrating an example power amplifier 200b. Power amplifier 200b is similar to power amplifier 200a previously described and illustrated with reference to FIG. 2A, except that power amplifier 200b includes driver stages 270 and 280 and additional example details for control logic 240 and 260. In some examples, each cell of the main SCPA 112 may include driver stages 270. In other examples, as illustrated in FIG. 2A, driver stages 270 may be excluded. Driver stages 270 may include a first driver stage (e.g., inverter 271, and/or inverter 272, and/or additional inverters) connected between a first output of control logic 240 and the input (e.g., both the high side switch and the low side switch) of the first inverter 248. Driver stages 270 may also include a second driver stage (e.g., inverter 273, and/or inverter 274, and/or additional inverters) connected between a second output of control logic 240 and the first input (e.g., the high side switch) of the second inverter 250. Driver stages 270 may also include a third driver stage (e.g., inverter 275, and/or inverter 276, and/or additional inverters) connected between a third output of control logic 240 and the second input (e.g., the low side switch) of the second inverter 250. In some examples, each cell of the peak SCPA 114 may include driver stage 280. In other examples, as illustrated in FIG. 2A, driver stage 280 may be excluded. Driver stage 280 may include a fourth driver stage (e.g., inverter 281, and/or inverter 282, and/or additional inverters) connected between the output of control logic 260 and the input (e.g., both the high side switch and the low side switch) of the third inverter 264.

In some examples, control logic 240 may include a first AND gate 252, a delay 254, an OR gate 256, and a second AND gate 258. In other examples, control logic 240 may include another suitable combination of logic components. The first AND gate 252 receives the first control signal EN_{M0} and the LO_{M} signal to generate a first AND gate output signal. The OR gate 256 receives the second control signal EN_{M0_HP} and the first AND gate output signal to generate an OR gate output signal. The second AND gate 258 receives the second control signal EN_{M0_HP} and the first AND gate output signal to generate a second AND gate output signal. The delay 254 delays the first AND gate output signal to align the first AND gate output signal with the OR gate output signal and the second AND gate output signal. The output of the delay is electrically coupled to the input of the first inverter 248 through driver stage 270 (e.g., inverters 271 and 272). The output of OR gate 256 is electrically coupled to the first input (e.g., high side switch) of the second inverter 250 through driver stage 270 (e.g., inverters 273 and 274). The output of the second AND gate 258 is electrically coupled to the second input (e.g., low side switch) of the second inverter 250 through driver stage 270 (e.g., inverters 275 and 276). In some examples, second control logic 260 may include a third AND gate. In other examples, control logic 260 may include another suitable logic component or combination of logic components. The third AND gate 260 receives the second control signal EN_{P0} and the LO_{P} signal to generate a third AND gate output signal. The output of the third AND gate 260 is electrically coupled to the input of the third inverter 264 through driver stage 280 (e.g., inverters 281 and 282).

It is noted that the number of driving inverters (e.g., two in the illustrated example) is merely one example and any number of driving inverters (e.g., 1, 3, 4, 5, or more) may be used. The control logic gates (e.g., 252, 256, 258, 260) should be selected accordingly depending upon whether an even or odd number of driving inverters are used. Furthermore, it is noted that the first inverter 248 of each cell of the main SCPA 112 may also be implemented as a tri-state inverter with corresponding lineup without limiting the functionality of power amplifier 200b. The two part cells of main SCPA 112 may also be applied to asymmetric Doherty implementations.

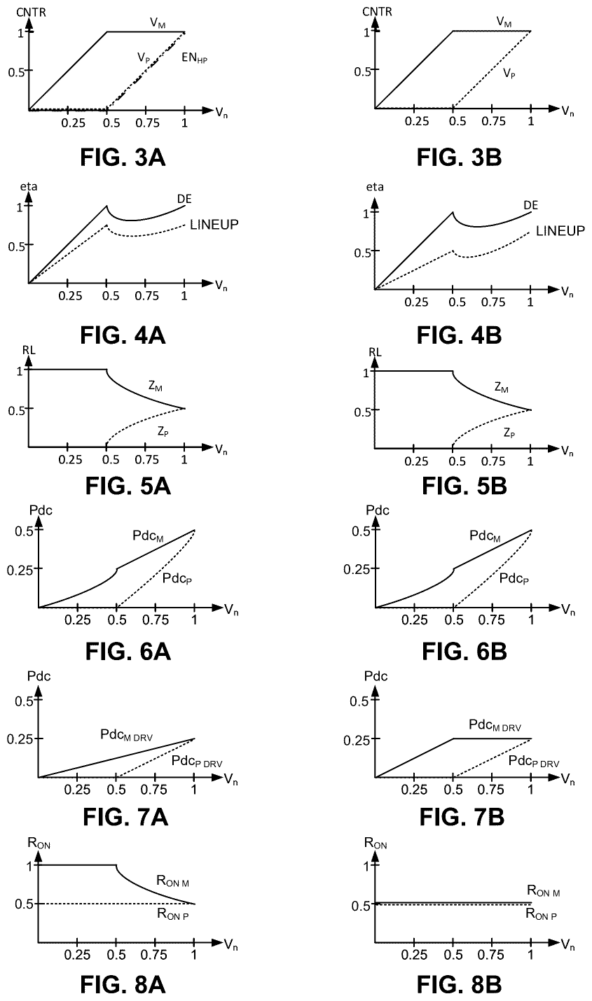

The following FIGS. 3A-8B are charts illustrating a comparison between a power amplifier including two part main SCPA cells each including a tri-state second inverter (e.g., 250 of FIGS. 2A and 2B), such as power amplifier 100, 200a, or 200b of FIGS. 1-2B, represented by FIGS. 3A, 4A, 5A, 6A, 7A, and 8A versus a power amplifier having a similar structure but not including two part main SCPA cells (i.e., without the tri-state second inverter within each main SCPA cell) represented by FIGS. 3B, 4B, 5B, 6B, 7B, and 8B.

FIG. 3A illustrates normalized control signals (CNTR) versus normalized output voltage (Vₙ) for a power amplifier including two part main SCPA cells each including a tri-state second inverter 250. The normalized control signals may correspond to the control signal A of FIG. 1. The portion of the normalized output voltage provided by the main SCPA 112 (e.g., on signal path 113) is controlled by the control signal V_{M} (e.g., on signal path 132 and/or 108 of FIG. 1) and the control signal EN_{HP} (e.g., on signal path 111 of FIG. 1). The portion of the normalized output voltage provided by the peak SCPA 114 (e.g., on signal path 115) is controlled by the control signal V_{P} (e.g., on signal path 136 and/or 110 of FIG. 1).

With no cells active based on control signals V_{M}, EN_{HP}, and V_{P}, the normalized output voltage is 0 Vn. As the first inverter 248 of each cell of the main SCPA 112 is sequentially activated as indicated by control signal V_{M} increasing linearly from 0 CNTR to 1 CNTR, the normalized output voltage linearly increases from 0 Vₙ to 0.5 Vₙ where the first inverter 248 of all the cells of main SCPA 112 are activated. As each cell of the peak SCPA 114 is sequentially activated as indicated by control signal V_{P} increasing linearly from 0 CNTR to 1 CNTR and as each tri-state second inverter 250 of each cell of the main SCPA 112 is sequentially activated as indicated by control signal EN_{HP} also increasing linearly from 0 CNTR to 1 CNTR, the normalized output voltage linearly increases from 0.5 Vₙ to 1 Vₙ where all the cells of peak SCPA 114 and the tri-state inverter 250 of all the cells of main SCPA 112 are activated. FIG. 3B illustrates normalized control signals (CNTR) versus a normalized output voltage (Vₙ) for a power amplifier not including a tri-state second inverter 250 in each main SCPA cell. As shown in FIG. 3B, control signals V_{M} and V_{P} are identical to control signals V_{M} and V_{P} of FIG. 3A, but the control signal EN_{HP} is excluded since there are no tri-state second inverters to control.

FIG. 4A illustrates normalized efficiencies (eta) versus the normalized output voltage (Vₙ) for a power amplifier including main SCPA cells each including a tri-state second inverter 250. The drain efficiency (DE) (e.g., power delivered to the load divided by the power consumed by the final stage of the power amplifier) and the lineup efficiency (LINEUP) (e.g., power delivered to the load divided by the total power consumed by the final stage and driving stages of the power amplifier) are shown. FIG. 4B illustrates the normalized efficiencies (eta) versus the normalized output voltage (Vₙ) for a power amplifier not including a tri-state second inverter 250 in each main SCPA cell. Due to the tri-state second inverter 250 of each main SCPA cell, the lineup efficiency is improved as illustrated in FIG. 4A compared to FIG. 4B due to the reduced capacitive switching losses inside the two part cells of main SCPA 112.

FIG. 5A illustrates normalized load resistances (RL) versus the normalized output voltage (Vₙ) for a power amplifier including main SCPA cells each including a tri-state second inverter 250. The impedance of the main SCPA 112 (e.g., presented at the transformer 116) is indicated by Z_{M} and the impedance of the peak SCPA 114 (e.g., presented at the transformer 116) is indicated by Z_{P}. Z_{M} remains constant at 1 RL and Z_{P} remains constant at 0 RL until the first inverter 248 of all the cells of the main SCPA 112 are active at 0.5 Vₙ. Z_{M} then decreases to 0.5 RL and Z_{P} increases to 0.5 RL as each cell of the peak SCPA 114 is activated and each tri-state second inverter 250 of the main SCPA 112 is activated until the normalized output voltage is 1 Vn. FIG. 5B illustrates the normalized load resistances (RL) versus the normalized output voltage (Vₙ) for a power amplifier not including a tri-state second inverter 250 in each main SCPA cell. As illustrated in FIGS. 5A and 5B, Z_{M} and Z_{P} are identical in both FIGS. 5A and 5B.

FIG. 6A illustrates normalized DC power (Pdc) versus the normalized output voltage (Vₙ) for a power amplifier including main SCPA cells each including a tri-state second inverter 250. The DC power for the main SCPA cells (Pdc_{M}) and the peak SCPA cells (Pdc_{P}) are indicated. FIG. 6B illustrates normalized DC power (Pdc) versus the normalized output voltage (Vₙ) for a power amplifier not including a tri-state second inverter 250 in each main SCPA cell. As illustrated in FIGS. 6A and 6B, Pdc_{M} and Pdcp are identical in both FIGS. 6A and 6B.

FIG. 7A illustrates normalized DC power (Pdc) versus the normalized output voltage (Vₙ) for a power amplifier including main SCPA cells each including a tri-state second inverter 250. The DC power for the driving stage(s) of the main SCPA cells (PdC_{M DRV}) and the driving stages of the peak SCPA cells (Pdc_{P DRV}) are indicated. Pdc_{M DRV} increases linearly between 0 Pdc and 0.25 Pdc as the first inverter 248 of each cell of the main SCPA 112 is activated between 0 Vₙ and 0.5 Vₙ and as each tri-state second inverter 250 is activated between 0.5 Vₙ and 1 Vₙ. Pdc_{P DRV} increases linearly between 0 Pdc and 0.25 Pdc as each cell of the peak SCPA 114 is activated between 0.5 Vₙ and 1 Vₙ. FIG. 7B illustrates normalized DC power (Pdc) versus the normalized output voltage (Vₙ) for a power amplifier not including a tri-state second inverter 250 in each main SCPA cell. As illustrated in FIG. 7B, Pdc_{M DRV} increases linearly between 0 Pdc and 0.25 Pdc as each cell of the main SCPA is activated and Pdc_{M DRV} remains constant once the peak SCPA becomes active between 0.5 Vₙ and 1 Vₙ. Pdc_{P DRV} is identical in both FIGS. 7A and 7B. Thus, as illustrated in FIG. 7A, Pdc_{P DRV} is decreased at lower voltage/power levels due to the two part main SCPA cells each including a tri-state second inverter 250.

FIG. 8A illustrates normalized on resistances (RON) versus the normalized output voltage (Vₙ) for a power amplifier including main SCPA cells each including a tri-state second inverter 250. The on resistance of the main SCPA (R_{ON M}) is twice the output resistance of the peak SCPA (R_{ON P}) and remains constant at 1 R_{ON} until the first inverter 248 of all the main SCPA cells are active, then R_{ON M} is reduced from 1 R_{ON} to 0.5 R_{ON} as the tri-state second inverters 250 of the main SCPA cells are activated. The on resistance of the peak SCPA (R_{ON P}) remains constant at 0.5 R_{ON}. FIG. 8B illustrates normalized on resistances (R_{ON}) versus the normalized output voltage (Vₙ) for a power amplifier not including a tri-state second inverter 250 in each main SCPA cell. As illustrated in FIG. 8B, R_{ON M} and R_{ON P} both remain constant at 0.5 R_{ON} between 0 Vₙ and 1 Vₙ.

In summary, for a typical power amplifier not including two part main SCPA cells, as shown in FIG. 7B, Pdc_{M DRV} remains constant and as shown in FIG. 8B, R_{ON M} remains constant once the peak SCPA 114 becomes active. On the other hand, as shown in FIG. 5B, Z_{M} decreases as higher output power is achieved. Therefore, the on resistance of the main SCPA is sized for the peak power operation, whereas in the back-off operation the on resistance is not the main contributor to losses. In back-off, the power consumed by the driving stages in the lineup dominate the losses, thus imposing a limit to the lineup efficiency in back-off as shown in FIG. 4B, especially for asymmetric Doherty implementations where the ratio between peak and back-off power is large.

Accordingly, the power amplifiers (e.g., 100, 200a, 200b) disclosed herein use a configurable driver. Instead of having a single inverter based final stage, each cell is split into two parts including a fixed part that is always on (e.g., first inverter 248) and configurable part (e.g., tri-state second inverter 250) that can be disabled to reduce the lineup switching losses as shown in FIG. 4A. To enable the switch off of a part of the lineup, the corresponding final stage provides tri-state capability. This tri-state capability may be achieved by providing the driving signals to the low side and high side switches separately, as shown in FIGS. 2A and 2B. Any delays between the part that is always on and the part that can be disabled should be addressed to prevent the introduction of unwanted amplitude to phase (AM to PM) effects. These delays may be addressed by a delay (e.g., 254) to match a delay of logic circuits (e.g., 256 and/or 258) in the control logic (e.g., 240). In the low power region, only the upper part (e.g., first inverter 248) of the main SCPA driver is active and thus the DC power consumption of the driving stage is reduced as shown in FIG. 7A. At the same time, the on resistance R_{ON M} is increased (FIG. 8A) in the same way as the load impedance Z_{M} (FIG. 5A) for the back-off condition and follows the load modulation of the main SCPA, thus providing a constant ratio. By implementing the two part main SCPA as disclosed herein, an additional degree of freedom is provided for optimizing the capacitive lineup losses and resistive losses for peak power and back-off conditions independently.

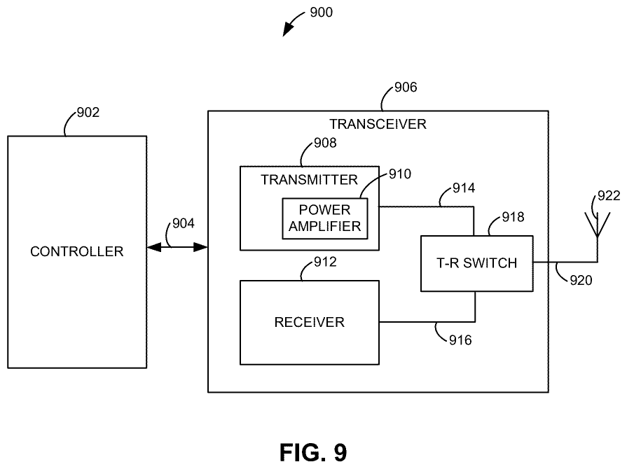

FIG. 9 is a block diagram illustrating one example of a system 900. System 900 may include a controller 902 and a transceiver 906. Controller 902 is communicatively coupled to transceiver 906 through a communication path 904. Transceiver 906 may include a transmitter 908, a receiver 912, a transmit-receive (T-R) switch 918, and an antenna 922. In some examples, transmitter 908 may include a power amplifier 910, such as power amplifier 100, 200a, or 200b, as previously described and illustrated with reference to FIGS. 1-2B to achieve low power consumption by enabling high efficiency even at output power back-off. Transmitter 908 is electrically coupled to T-R switch 918 through a signal path 914. Receiver 912 is electrically coupled to T-R switch 918 through a signal path 916. T-R switch 918 is electrically coupled to antenna 922 through a signal path 920.

Controller 902 may include a Central Processing Unit (CPU), a microprocessor, a microcontroller, an Application Specific Integrated Circuit (ASIC), a Field-Programmable Gate Array (FPGA), or other suitable logic circuitry for controlling the operation of transceiver 906. In some examples, transceiver 906 may include a Wi-Fi or Bluetooth transceiver. Transmitter 908 is configured to transmit signals provided by controller 902 via antenna 922, and receiver 912 is configured to receive signals via antenna 922 and pass the received signals to controller 902. T-R switch 918 connects transmitter 908 to antenna 922 to transmit signals via antenna 922 and connects receiver 912 to antenna 922 to receive signals via antenna 922.

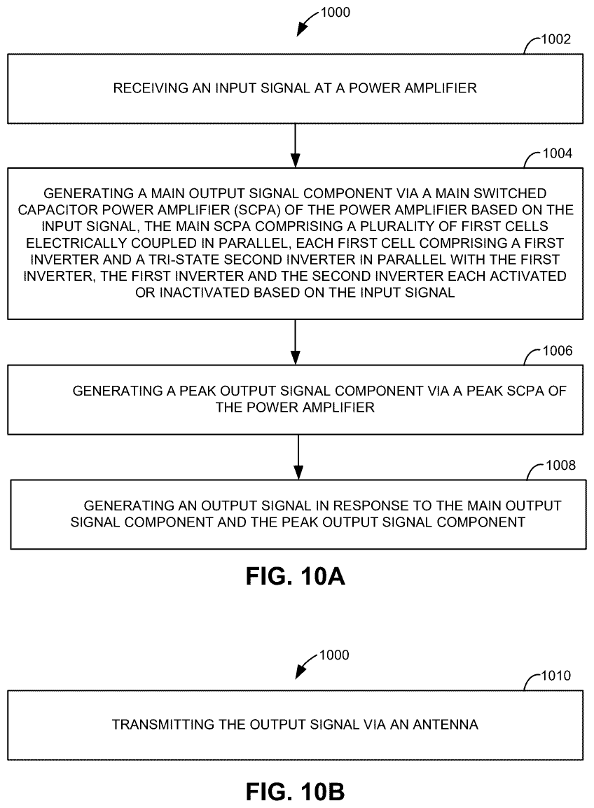

FIGS. 10A and 10B are flow diagrams illustrating an example method 1000 for generating an output signal via a power amplifier, such as power amplifier 100, 200a, or 200b as previously described and illustrated with reference to FIGS. 1-2B. As illustrated in FIG. 10A at 1002, method 1000 includes receiving an input signal (e.g., signal A of FIG. 1) at a power amplifier. At 1004, method 1000 includes generating a main output signal component (e.g., on signal path 113 of FIGS. 1-2B) via a main switched capacitor power amplifier (SCPA) (e.g., 112) of the power amplifier based on the input signal, the main SCPA comprising a plurality of first cells electrically coupled in parallel, each first cell comprising a first inverter (e.g., 248) and a tri-state second inverter (250) in parallel with the first inverter, the first inverter and the second inverter each activated or inactivated based on the input signal. At 1006, method 1000 includes generating a peak output signal component (e.g., on signal path 115 of FIGS. 1-2B) via a peak SCPA (e.g., 114) of the power amplifier. At 1008, method 1000 includes generating an output signal in response to the main output signal component and the peak output signal component. As illustrated in FIG. 10B at 1010, method 1000 may further include transmitting the output signal via an antenna (e.g., 922 of FIG. 9).

In some examples, generating the main output signal component via the main SCPA comprises selecting a first number of active first inverters and a second number of active second inverters of the plurality of first cells based on the input signal, and generating the peak output signal component via the peak SCPA comprises selecting the second number of active second cells of a plurality of second cells of the peak SCPA based on the input signal. In some examples, generating the main output signal component via the main SCPA comprises driving a first driver stage (e.g., 270) prior to the first inverter and the second inverter. In some examples, a DC power consumption of the main SCPA increases linearly between zero active second inverters and a maximum number of active second inverters of the plurality of first cells (e.g., FIG. 7A). In some examples, an on resistance of the main SCPA decreases between zero active second inverters and a maximum number of active second inverters of the plurality of first cells (e.g., FIG. 8A).

It is to be understood that the features of the various exemplary embodiments described herein may be combined with each other, unless specifically noted otherwise.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

What is claimed is:

1. A power amplifier comprising:
a main switched capacitor power amplifier (SCPA); and
a peak SCPA in parallel with the main SCPA,
wherein the main SCPA comprises a plurality of first cells electrically coupled in parallel, each first cell comprising:
a first inverter;
a tri-state second inverter in parallel with the first inverter;
a first capacitor electrically coupled in series with the first inverter and the second inverter; and
first control logic to apply a local oscillator (LO) signal to the first inverter or set the first inverter to a static logic state in response to a first control signal, and apply the LO signal to the second inverter or set the second inverter to a high-impedance state in response to a second control signal.

2. The device of claim 1, wherein each first inverter comprises a first high side switch and a first low side switch connected to the first high side switch at a first drain node,
wherein each tri-state second inverter comprises a second high side switch and a second low side switch connected to the second high side switch at a second drain node,
wherein each first cell further comprises:
a first driver stage connected to the first high side switch and the first low side switch of the first inverter;
a second driver stage connected to the second high side switch of the second inverter; and
a third driver stage connected to the second low side switch of the second inverter.

3. The device of claim 1, wherein the first control logic comprises:
a first AND gate to receive the first control signal and the LO signal to generate a first AND gate output signal;
an OR gate to receive the second control signal and the first AND gate output signal to generate an OR gate output signal;
a second AND gate to receive the second control signal and the first AND gate output signal to generate a second AND gate output signal; and
a delay to delay the first AND gate output signal to align the first AND gate output signal with the OR gate output signal and the second AND gate output signal;
wherein an output of the delay is electrically coupled to an input of the first inverter;
wherein an output of the OR gate is electrically coupled to a first input of the second inverter; and
wherein an output of the second AND gate is electrically coupled to a second input of the second inverter.

4. The device of claim 1, wherein the peak SCPA comprises a plurality of second cells, each second cell comprising:
a third inverter;
a second capacitor electrically coupled in series with the third inverter; and
second control logic to apply the LO signal to the third inverter or set the third inverter to a static logic state in response to the second control signal.

5. The device of claim 4, wherein each second cell further comprises a fourth driver stage electrically coupled between the second control logic and the third inverter;

6. The device of claim 4, wherein the second control logic comprises:
a third AND gate to receive the second control signal and the LO signal to generate a third AND gate output signal;
wherein an output of the third AND gate is electrically coupled to an input of the third inverter.

7. A system comprising:
a controller;
a transceiver communicatively coupled to the controller, the transceiver comprising a power amplifier; and
an antenna circuit electrically coupled to the transceiver,
wherein the power amplifier comprises:
a main switched capacitor power amplifier (SCPA); and
a peak SCPA in parallel with the main SCPA,
wherein the main SCPA comprises a plurality of first cells electrically coupled in parallel, each first cell comprising:
a first inverter;
a tri-state second inverter in parallel with the first inverter;
a first capacitor electrically coupled in series with the first inverter and the second inverter; and
first control logic to apply a local oscillator (LO) signal to the first inverter or set the first inverter to a static logic state in response to a first control signal, and apply the LO signal to the second inverter or set the second inverter to a high-impedance state in response to a second control signal.

8. The system of claim 7, wherein each first inverter comprises a first high side switch and a first low side switch connected to the first high side switch at a first drain node,
wherein each tri-state second inverter comprises a second high side switch and a second low side switch connected to the second high side switch at a second drain node,
wherein each first cell further comprises:
a first driver stage connected to the first high side switch and the first low side switch of the first inverter;
a second driver stage connected to the second high side switch of the second inverter; and
a third driver stage connected to the second low side switch of the second inverter.

9. The system of claim 7, wherein the first control logic comprises:
a first AND gate to receive the first control signal and the LO signal to generate a first AND gate output signal;
an OR gate to receive the second control signal and the first AND gate output signal to generate an OR gate output signal;
a second AND gate to receive the second control signal and the first AND gate output signal to generate a second AND gate output signal; and
a delay to delay the first AND gate output signal to align the first AND gate output signal with the OR gate output signal and the second AND gate output signal;
wherein an output of the delay is electrically coupled to an input of the first inverter;
wherein an output of the OR gate is electrically coupled to a first input of the second inverter; and
wherein an output of the second AND gate is electrically coupled to a second input of the second inverter.

10. The system of claim 7, wherein the peak SCPA comprises a plurality of second cells, each second cell comprising:
a third inverter;
a second capacitor electrically coupled in series with the third inverter; and
second control logic to apply the LO signal to the third inverter or set the third inverter to a static logic state in response to the second control signal.

11. The system of claim 10, wherein each second cell further comprises a fourth driver stage electrically coupled between the second control logic and the third inverter.

12. The system of claim 10, wherein the second control logic comprises:
a third AND gate to receive the second control signal and the LO signal to generate a third AND gate output signal;
wherein an output of the third AND gate is electrically coupled to an input of the third inverter.

13. The system of claim 7, wherein the power amplifier comprises a class-D amplifier.

14. The system of claim 7, wherein the transceiver comprises a Bluetooth or Wi-Fi transceiver.

15. A method comprising:
receiving an input signal at a power amplifier;
generating a main output signal component via a main switched capacitor power amplifier (SCPA) of the power amplifier based on the input signal, the main SCPA comprising a plurality of first cells electrically coupled in parallel, each first cell comprising a first inverter and a tri-state second inverter in parallel with the first inverter, the first inverter and the second inverter each activated or inactivated based on the input signal;
generating a peak output signal component via a peak SCPA of the power amplifier; and
generating an output signal in response to the main output signal component and the peak output signal component.

16. The method of claim 15, further comprising:
transmitting the output signal via an antenna.

17. The method of claim 15, wherein generating the main output signal component via the main SCPA comprises selecting a first number of active first inverters and a second number of active second inverters of the plurality of first cells based on the input signal, and
wherein generating the peak output signal component via the peak SCPA comprises selecting the second number of active second cells of a plurality of second cells of the peak SCPA based on the input signal.

18. The method of claim 15, wherein generating the main output signal component via the main SCPA comprises driving a first driver stage prior to the first inverter and the second inverter.

19. The method of claim 15, wherein a DC power consumption of the main SCPA increases linearly between zero active second inverters and a maximum number of active second inverters of the plurality of first cells.

20. The method of claim 15, wherein an on resistance of the main SCPA decreases between zero active second inverters and a maximum number of active second inverters of the plurality of first cells.
